(19) United States
(12) Patent Application Publication
(10) Pub. No.: US 2017/0062203 A1
(43) Pub. Date: Mar. 2, 2017

(54) Method of Preparing Liquid Chemical for Forming Protective Film

(71) Applicant: Central Glass Company, Limited, Ube-shi (JP)

(72) Inventors: Atsushi RYOKAWA, Ube-shi (JP); Shuhei YAMADA, Ube-shi (JP); Masahiro FUJITANI, Sanyoonoda-shi (JP); Soichi KUMON, Matsusaka-shi (JP); Masanori SAITO, Matsusaka-shi (JP); Takashi SAIO, Suzuka-shi (JP); Shinobu ARATA, Matsusaka-shi (JP)

(21) Appl. No.: 15/348,383

(22) Filed: Nov. 10, 2016

Related U.S. Application Data
(62) Division of application No. 13/688,856, filed on Nov. 29, 2012.

(30) Foreign Application Priority Data
Nov. 29, 2011 (JP) 2011-260869

(51) Int. Cl. H01L 21/02; C09D 7/12; B08B 3/08

(52) U.S. Cl. CPC H01L 21/0206; B08B 3/08; C09D 7/1233

(57) ABSTRACT

[Problem] To provide a method for preparing a protective film-forming liquid chemical, in a method for producing a wafer having at its surface an uneven pattern and containing silicon element at least at a part of the uneven pattern. The liquid chemical forms a water-repellent protective film on the uneven pattern of the wafer and improves a cleaning step which tends to induce a pattern collapse, and particularly provides a good persistence (pot life) of the improving effect.

[Solution] A method for preparing a liquid chemical for forming a water-repellent protective film, the liquid chemical being for forming a water-repellent protective film at the time of cleaning the wafer at least on surfaces of recessed portions of the uneven pattern, the liquid chemical containing a nonaqueous organic solvent, a silylation agent, and an acid or base. The method for preparing a liquid chemical for forming a water-repellent protective film is characterized by including:
a dehydrating step for adjusting a water content of the nonaqueous organic solvent to 200 mass ppm or less; and
a mixing step for mixing the nonaqueous organic solvent, the silylation agent, and the acid or base after the dehydrating step.

### TECHNICAL FIELD

The present invention relates to a technique for cleaning a substrate (a wafer) in semiconductor device manufacturing and the like, the objective of which is to improve the production yield of devices having a circuit pattern. The present invention particularly relates to: a liquid chemical for forming a water-repellent protective film, the objective of which is to improve a cleaning step which tends to induce a wafer having an uneven pattern at its surface to cause a collapse of the uneven pattern; and a method for preparing the same.

### BACKGROUND OF THE INVENTION

Semiconductor devices for use in networks or digital household electric appliances are being further desired to be sophisticated, multifunctional, and low in power consumption. Accordingly, the trend toward micro-patterning for circuits has been developed, with which micro-sizing of particles has so advanced as to cause reduction of production yield. As a result of this, a cleaning step for the purpose of removing contaminants such as the micro-sized particles and the like is frequently used. As a result of this, 30-40% of the whole of the semiconductor fabrication process is occupied with the cleaning step.

On the other hand, at the time of cleaning as conventionally performed with an ammonia-mixed cleaning agent, damages to a wafer due to the basicity has been getting serious together with the trend toward micro-patterning for circuits. Therefore, alternation with a less damaging one, i.e., a dilute hydrofluoric acid-based cleaning agent is taking place.

With this, problems about the damages to the wafer due to cleaning have been solved; however, problems due to an aspect ratio increased with the trend toward micro-processing in the semiconductor devices have become obvious. In other words, a phenomenon where the pattern causes a collapse when a gas-liquid interface passes through the pattern is brought about after cleaning or rinsing so as to largely reduce the yield, which has become a significant problem.

The pattern collapse occurs at the time of drawing the wafer out of a cleaning liquid or a rinsing liquid. The reason thereof is said that a difference in height of residual liquid between a part having a high aspect ratio and that having a low aspect ratio makes a difference in capillary force which acts on the pattern.

Accordingly, the pattern collapse is excepted to be solved by reducing the capillary force to decrease the difference in capillary force due to the difference in height of the residual liquid. The magnitude of the capillary force is the absolute value of P obtained by the equation as shown below. From this equation, it is expected that the capillary force can be reduced by decreasing γ or cos θ.

P=2×γ×cos θ/S

(γ: Surface tension, θ: Contact angle, S: Pattern width (the widths of the recessed portions))

In Patent Publication 1, there is disclosed a cleaning process in which a wafer surface provided to have an uneven pattern with a film containing silicon is surface-reformed by oxidation or the like and a water-repellent protective film is formed on the surface by using a water-soluble surfactant or a silane coupling agent thereby reducing the capillary force to prevent the pattern collapse. However, the water-repellent agent used therein is sometimes insufficient in water repellency-imparting effect and in its pot life.

Additionally, in Patent Publications 2 to 4, there is disclosed that a cleaning step which tends to induce a pattern collapse can be improved by using a water-repellent cleaning liquid for imparting water-repellency at least to recessed portions of an uneven pattern of a silicon wafer; however, these are susceptible to improvement in terms of the pot life of the cleaning liquid.

### PRIOR ART DOCUMENTS

### Patent Publications

Patent Publication 1: Japanese Patent No. 4403202
Patent Publication 2: Japanese Patent Application Publication No. 2010-192878
Patent Publication 3: Japanese Patent Application Publication No. 2010-192879
Patent Publication 4: Japanese Patent Application Publication No. 2010-272852

### SUMMARY OF THE INVENTION

### Problems to be Solved by the Invention

At the time of fabricating a semiconductor device, a surface of a wafer is made into a surface formed having an uneven pattern. An object of the present invention is, in a method for producing a wafer having at its surface an uneven pattern and containing silicon element at least at a part of the uneven pattern (the wafer will hereinafter be referred to as “a silicon wafer” or merely as “a wafer”), to provide: a liquid chemical for forming a protective film, the liquid chemical being able to form a water-repellent protective film on the uneven pattern of the wafer while improving a cleaning step which tends to induce a pattern collapse particularly with a good persistence (pot life) of the improving effect; and a method for preparing the liquid chemical. A further object of the present invention is to provide: a method for preparing a liquid chemical kit for forming a water-repellent protective film which kit is able to produce the liquid chemical by mixing; and the liquid chemical kit.

### Means for Solving the Problems

In the present invention, a water-repellent protective film means a film formed on a wafer surface so as to reduce the wettability of the wafer surface, i.e., a film imparting water repellency to the surface. In the present invention, “water repellency” means to decrease a surface energy of a surface of an article thereby weakening the interaction between water or another liquid and the surface of the article (i.e., at the interface) such as a hydrogen bond, intermolecular forces and the like. The effect of reducing the interaction is particularly exhibited against water, but it is also exhibited against a mixture liquid of water and a liquid other than water or against a liquid other than water. With the reduction of the interaction, the contact angle of the liquid to the article surface can be increased. Hereinafter, the water-repellent protective film may be referred to merely as “a protective film”.

If a treatment of a wafer is performed with the use of the liquid chemical of the present invention, the protective film is formed at least on surfaces of recessed portions of the uneven pattern of a wafer when a cleaning liquid is removed from or dried out of the recessed portions, so that the capillary force is lowered and therefore a pattern collapse becomes difficult to occur.

A first embodiment of the present invention (the embodiment may hereinafter be referred to as “a first method”) is a method for preparing a liquid chemical for forming a water-repellent protective film (the liquid chemical may hereinafter be referred to as “a protective film-forming liquid chemical” or merely as “a liquid chemical”), the liquid chemical being for forming a water-repellent protective film at the time of cleaning a wafer having at its surface an uneven pattern and containing silicon element at least at a part of the uneven pattern at least on surfaces of recessed portions of the uneven pattern, the liquid chemical comprising a nonaqueous organic solvent, a silylation agent, and an acid or base. The method is characterized by comprising:

a dehydrating step for adjusting a water content of the nonaqueous organic solvent to 200 mass ppm or less; and
a mixing step for mixing the nonaqueous organic solvent, the silylation agent, and the acid or base after the dehydrating step.

In the dehydrating step, the water content of the nonaqueous organic solvent is adjusted to 200 mass ppm or less. With this, a reduction of the activity of the silylation agent and the acid or base, due to hydrolysis and the like, becomes difficult to occur at the time of mixing the nonaqueous organic solvent, the silylation agent, and the acid or base in the subsequent mixing step; therefore, it is possible to impart an excellent water repellency to the surfaces of the recessed portions of the wafer by using the thus obtained liquid chemical. Further, deteriorations with time of the silylation agent, and the acid or base contained in the liquid chemical are eased down, so that the liquid chemical gains a great pot life. Furthermore, a nonaqueous organic solvent having a water content of 100 mass ppm or less, preferably 50 mass ppm or less is more preferable because the liquid chemical gains the water repellency-imparting effect and the pot life more excellently. Incidentally, the water content of the nonaqueous organic solvent after the dehydrating step is required only to be within the above-mentioned range and therefore it may be not lower than 0.1 mass ppm. Moreover, the measurement of the water content in the present invention may be achieved by a measurement using Karl Fischer's moisture meter, for example.

The dehydrating step is preferably at least one selected from the group consisting of a step of purifying the nonaqueous organic solvent by distillation, a step of removing water from the solvent by adding an insoluble water-absorbing agent to the nonaqueous organic solvent, a step of performing a substitution by a dried inert gas under exposure to air, and a step of heating or vacuum heating.

Additionally, the insoluble water-absorbing agent added to the nonaqueous organic solvent is preferably at least one selected from the group consisting of zeolite, phosphorus pentoxide, silica gel, calcium chloride, sodium sulfate, magnesium sulfate, anhydrous zinc chloride, fuming sulfuric acid and soda lime.

As the nonaqueous organic solvent used in the first method of the present invention, it is possible to concretely cite: hydrocarbons such as toluene, benzene, xylene, hexane, heptane, octane and the like; esters such as ethyl acetate, propyl acetate, butyl acetate, ethyl acetoacetate and the like; ethers such as diethyl ether, dipropyl ether, dibutyl ether, tetrahydrofuran, dioxane and the like; ketones such as acetone, acetylacetone, methyl ethyl ketone, methyl propyl ketone, methyl butyl ketone, cyclohexanone, isophorone and the like; halogen-containing solvents including perfluorocarbons such as perfluorooctane, perfluorononane, perfluorocyclopentane, perfluorocyclohexane, hexafluorobenzene and the like, hydrofluorocarbons such as 1,1,1,3,3-pentafluorobutane, octafluorocyclopentane, 2,3-dihydrodecafluoropentane, ZEORORA-H (produced by ZEON CORPORATION) and the like, hydrofluoroethers such as methyl perfluoroisobutyl ether, methyl perfluorobutyl ether, ethyl perfluorobutyl ether, ethyl perfluoroisobutyl ether, ASAHIKLIN AE-3000 (produced by Asahi Glass Co., Ltd.), Novec 7100, Novec 7200, Novec 7300, Novec 7600 (any of these are produced by 3M Limited) and the like, chlorocarbons such as tetrachloromethane and the like, hydrochlorocarbons such as chloroform and the like, chlorofluorocarbons such as dichlorodifluoromethane and the like, hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, 1,2-dichloro-3,3,3-trifuoropropene and the like, perfluoroethers, perfluoropolyethers and the like; sulfoxide-based solvents such as dimethyl sulfoxide and the like, lactone-based solvents such as γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone and the like; carbonate-based solvents such as dimethyl carbonate, ethyl methyl carbonate, diethyl carbonate, propylene carbonate and the like; alcohols such as methanol, ethanol, propanol, butanol, ethylene glycol, diethylene glycol, 1,2-propanediol, 1,3-propanediol, dipropylene glycol, 1,2-butanediol, 1,3-butanediol, 1,4-butanediol, triethylene glycol, tripropylene glycol, tetraethylene glycol, tetrapropylene glycol, glycerine and the like; polyalcohol derivatives such as ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether, butylene glycol monomethyl ether, ethylene glycol dimethyl ether, ethylene glycol diethyl ether, ethylene glycol dibutyl ether, ethylene glycol monomethyl ether acetate, ethylene glycol monoethyl ether acetate, ethylene glycol monobutyl ether acetate, ethylene glycol diacetate, diethylene glycol dimethyl ether, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol dimethyl ether, propylene glycol diethyl ether, propylene glycol dibutyl ether, propylene glycol monomethyl ether acetate, propylene glycol monoethyl ether acetate, propylene glycol monobutyl ether acetate, propylene glycol diacetate, dipropylene glycol dimethyl ether, dipropylene glycol methyl propyl ether, dipropylene glycol diethyl ether, dipropylene glycol dibutyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol dimethyl ether, butylene glycol monomethyl ether acetate, butylene glycol diacetate, glycerine triacetate and the like; and nitrogen element-containing solvents such as formamide, N,N-dimethylformamide, N,N-dimethylacetamide, N-methyl-2-pyrrolidone, diethylamine, triethylamine, pyridine and the like.

The nonaqueous organic solvent is preferably at least one selected from the group consisting of hydrocarbons, esters, ethers, ketones, halogen-containing solvents, sulfoxide-based solvents, lactone-based solvents, carbonate-based solvents, polyalcohol derivatives having no OH group, and nitrogen element-containing solvents having no N—H group. Since the silylation agent is reactive with a nonaqueous organic solvent having OH group or N—H group, there is a fear that the reactivity of the silylation agent is reduced if the nonaqueous organic solvent having OH group or N—H group is used as the nonaqueous organic solvent. As a result, the water repellency may become difficult to be exhibited in a short time. On the other hand, if a nonaqueous organic solvent having neither OH group nor N—H group is used as the nonaqueous organic solvent, the reactivity of the silylation agent becomes resistant to reduction and the water repellency is easily exhibited in a short time since the silylation agent is not reactive with the nonaqueous organic solvent having neither OH group nor N—H group. Incidentally, the nonaqueous organic solvent having neither OH group nor N—H group means either a nonaqueous polar organic solvent having neither OH group nor N—H group, or a nonaqueous nonpolar organic solvent having neither OH group nor N—H group.

Additionally, it is preferable to use a nonflammable one as a part or the entire of the nonaqueous organic solvent since the protective film-forming liquid chemical becomes nonflammable or increases in flash point thereby reducing the risk of the liquid chemical. Most of the halogen-containing solvents are nonflammable, and such a halogen-containing nonflammable solvent can be preferably used as a nonflammable organic solvent.

Additionally, it is preferable in view of safety under the fire protection law to use a solvent having a flash point exceeding 70° C. as the nonaqueous organic solvent.

Moreover, according to “Globally Harmonized System of Classification and Labelling of Chemicals; GHS”, a solvent having a flash point of not higher than 93° C. is defined as “a flammable liquid”. Therefore, when a solvent having a flash point exceeding 93° C. is used as the nonaqueous organic solvent, the protective film-forming liquid chemical tends to have a flash point exceeding 93° C. even if the solvent is not nonflammable one. Hence the liquid chemical hardly corresponds to “a flammable liquid” and therefore further preferable in view of safety.

Most of the lactone-based solvents, the carbonate-based solvents and the polyalcohol derivatives having no OH group have high flash point so as to be preferably used because the risk of the protective film-forming liquid chemical can be lowered. In view of the safety, a solvent having a flash point exceeding 70° C. is more preferably used as the nonaqueous organic solvent, which is concretely exemplified by γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone, propylene carbonate, ethylene glycol dibutyl ether, ethylene glycol monobutyl ether acetate, ethylene glycol diacetate, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol diacetate, dipropylene glycol methyl propyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol diacetate, glycerine triacetate and the like. It is further preferable to use a solvent having a flash point exceeding 93° C. as the nonaqueous organic solvent, which is concretely exemplified by γ-butyrolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone, propylene carbonate, ethylene glycol diacetate, diethylene glycol butyl methyl ether, diethylene glycol dibutyl ether, diethylene glycol diacetate, diethylene glycol monomethyl ether acetate, diethylene glycol monoethyl ether acetate, diethylene glycol monobutyl ether acetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol diacetate, dipropylene glycol diacetate, dipropylene glycol monomethyl ether acetate, dipropylene glycol monoethyl ether acetate, dipropylene glycol monobutyl ether acetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol diacetate, glycerine triacetate and the like.

Additionally, the silylation agent is preferably at least one selected from the group consisting of silicon compounds represented by the following general formula [1].

(R¹)ₐSi(H)_{b}X¹_{4-a-b} [1]

[In the formula [1], R¹ mutually independently represents a monovalent organic group having a C₁-C₁₈ monovalent hydrocarbon group the hydrogen elements of which may partially or entirely be replaced with a fluorine element(s). Additionally, X¹ mutually independently represents at least one group selected from the group consisting of a monovalent functional group of which element to be bonded to a silicon element is nitrogen, a monovalent functional group of which element to be bonded to a silicon element is oxygen, a halogen group, a nitrile group and —CO—NH—Si(CH₃)₃ group. a is an integer of from 1 to 3. b is an integer of from 0 to 2. The total of a and b is 1 to 3.]

R¹ of the general formula [1] decreases a surface energy of an article thereby reducing the interaction between water or another liquid and the surface of the article (i.e., at the interface) such as a hydrogen bond, intermolecular forces and the like. The effect of reducing the interaction is particularly exhibited against water, but it is also exhibited against a mixture liquid of water and a liquid other than water or against a liquid other than water. With this, the contact angle of the liquid to the article surface can be increased.

X¹ of the general formula [1] is a reactive moiety having reactivity against silanol group that serves as a reaction site of a silicon wafer. The reactive moiety and silanol group of a wafer cause reaction, i.e., the silylation agent is chemically bonded to silicon element of the silicon wafer through a siloxane bond, thereby forming the protective film. In cleaning of a silicon wafer using a cleaning liquid, if the protective film has been formed on the surfaces of the recessed portions of the wafer at the time of removing or drying the cleaning liquid out of the recessed portions of the wafer, the capillary force of the surfaces of the recessed portions is so lowered as to make a pattern collapse difficult to occur.

The monovalent functional group of which element to be bonded to silicon element is nitrogen, which is one example of X¹ of the general formula [1], may include not only hydrogen element, carbon element, nitrogen element and oxygen element but also silicon element, sulfur element and halogen element and the like. Examples of the functional group are an isocyanate group, amino group, dialkylamino group, isothiocyanate group, azide group, acetamide group, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring (the following formula [7]), oxazolidinone ring (the following formula [8]), morpholine ring (the following formula [9]), —NH—C(O)—Si(CH₃)₃, —N(H)₂₋ₕ(Si(H)ᵢR⁹₃₋ᵢ)ₕ (where R⁹ is a C₁-C₁₈ monovalent hydrocarbon group the hydrogen elements of which may partially or entirely be replaced with a fluorine element(s), h is an integer of 1 or 2, and i is an integer of from 0 to 2) and the like.

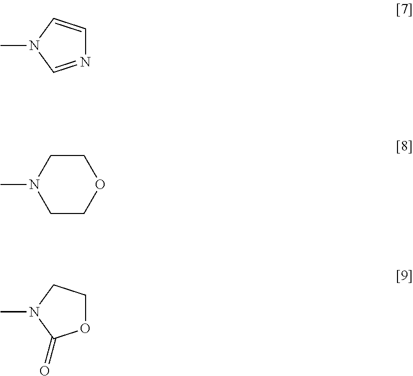

The monovalent functional group of which element to be bonded to silicon element is oxygen, which is one example of X¹ of the general formula [1], may include not only hydrogen element, carbon element, nitrogen element and oxygen element but also silicon element, sulfur element and halogen element and the like. Examples of the functional group are an alkoxy group, —OC(CH₃)═CHCOCH₃, —OC(CH₃)═N—Si(CH₃)₃, —OC(CF₃)═N—Si(CH₃)₃, —O—CO—R¹⁰ (where R¹⁰ is a C₁-C₁₈ monovalent hydrocarbon group the hydrogen elements of which may partially or entirely be replaced with a fluorine element(s)) and an alkyl sulfonate group the hydrogen elements of which may partially or entirely be replaced with a fluorine element(s) and the like.

Additionally, a halogen group, which is one example of X¹ of the general formula [1], is exemplified by a chloro group, bromo group, iodo group and the like.

As examples of the silylation agent represented by the general formula [1], it is possible to cite: alkylmethoxysilanes such as CH₃Si(OCH₃)₃, C₂H₅Si(OCH₃)₃, C₃H₇Si(OCH₃)₃, C₄H₉Si(OCH₃)₃, C₅H₁₁Si(OCH₃)₃, C₆H₁₃Si(OCH₃)₃, C₇H₁₅Si(OCH₃)₃, C₈H₁₇Si(OCH₃)₃, C₉H₁₉Si(OCH₃)₃, C₁₀H₂₁Si(OCH₃)₃, C₁₁H₂₃Si(OCH₃)₃, C₁₂H₂₅Si(OCH₃)₃, C₁₃H₂₇Si(OCH₃)₃, C₁₄H₂₉Si(OCH₃)₃, C₁₅H₃₁Si(OCH₃)₃, C₁₆H₃₃Si(OCH₃)₃, C₁₇H₃₅Si(OCH₃)₃, C₁₈H₃₇Si(OCH₃)₃, (CH₃)₂Si(OCH₃)₂, C₂H₅Si(CH₃)(OCH₃)₂, (C₂H₅)₂Si(OCH₃)₂, C₃H₇Si(CH₃)(OCH₃)₂, (C₃H₇)₂Si(OCH₃)₂, C₄H9Si(CH₃)(OCH₃)₂, (C₄H₉)₂Si(OCH₃)₂, C₅H₁₁Si(CH₃)(OCH₃)₂, C₆H₁₃Si(CH₃)(OCH₃)₂, C₇H₁₅Si(CH₃)(OCH₃)₂, C₈H₁₇Si(CH₃)(OCH₃)₂, C₉H₁₉Si(CH₃)(OCH₃)₂, C₁₀H₂₁Si(CH₃)(OCH₃)₂, C₁₁H₂₃Si(CH₃)(OCH₃)₂, C₁₂H₂₅Si(CH₃)(OCH₃)₂, C₁₃H₂₇Si(CH₃)(OCH₃)₂, C₁₄H₂₉Si(CH₃)(OCH₃)₂, C₁₅H₃₁Si(CH₃)(OCH₃)₂, C₁₆H₃₃Si(CH₃)(OCH₃)₂, C₁₇H₃₅Si(CH₃)(OCH₃)₂, C₁₈H₃₇Si(CH₃)(OCH₃)₂, (CH₃)₃SiOCH₃, C₂H5Si(CH₃)₂OCH₃, (C₂H₅)₂Si(CH₃)OCH₃, (C₂H₅)₃SiOCH₃, C₃H₇Si(CH₃)₂OCH₃, (C₃H₇)₂Si(CH₃)OCH₃, (C₃H7)₃SiOCH₃, C₄H₉Si(CH₃)₂OCH₃, (C₄H₉)₃SiOCH₃, C₅H₁₁Si(CH₃)₂OCH₃, C₆H₁₃Si(CH₃)₂OCH₃, C₇H₁₅Si(CH₃)₂OCH₃, C₈H₁₇Si(CH₃)₂OCH₃, C₉H₁₉Si(CH₃)₂OCH₃, C₁₀H₂₁Si(CH₃)₂OCH₃, C₁₁H₂₃Si(CH₃)₂OCH₃, C₁₂H₂₅Si(CH₃)₂OCH₃, C₁₃H₂₇Si(CH₃)₂OCH₃, C₁₄H₂₉Si(CH₃)₂OCH₃, C₁₅H₃₁Si(CH₃)₂OCH₃, C₁₆H₃₃Si(CH₃)₂OCH₃, C₁₇H₃₅Si(CH₃)₂OCH₃, C₁₈H₃₇Si(CH₃)₂OCH₃, (CH₃)₂Si(H)OCH₃, CH₃Si(H)₂OCH₃, (C₂H₅)₂Si(H)OCH₃, C₂H₅Si(H)₂OCH₃, C₂H₅Si(CH₃)(H)OCH₃, (C₃H₇)₂Si(H)OCH₃ and the like; fluoroalkylmethoxysilanes such as CF₃CH₂CH₂Si(OCH₃)₃, C₂F₅CH₂CH₂Si(OCH₃)₃, C₃F₇CH₂CH₂Si(OCH₃)₃, C₄F₉CH₂CH₂Si(OCH₃)₃, C₅F₁₁CH₂CH₂Si(OCH₃)₃, C₆F₁₃CH₂CH₂Si(OCH₃)₃, C₇F₁₅CH₂CH₂Si(OCH₃)₃, C₈F₁₇CH₂CH₂Si(OCH₃)₃, CF₃CH₂CH₂Si(CH₃)(OCH₃)₂, C₂F₅CH₂CH₂Si(CH₃)(OCH₃)₂, C₃F₇CH₂CH₂Si(CH₃)(OCH₃)₂, C₄F₉CH₂CH₂Si(CH₃)(OCH₃)₂, C₅F₁₁CH₂CH₂Si(CH₃)(OCH₃)₂, C₆F₁₃CH₂CH₂Si(CH₃)(OCH₃)₂, C₇F₁₅CH₂CH₂Si(CH₃)(OCH₃)₂, C₈F₁₇CH₂CH₂Si(CH₃)(OCH₃)₂, CF₃CH₂CH₂Si(CH₃)₂OCH₃, C₂F₅CH₂CH₂Si(CH₃)₂OCH₃, C₃F₇CH₂CH₂Si(CH₃)₂OCH₃, C₄F₉CH₂CH₂Si(CH₃)₂OCH₃, C₅F₁₁CH₂CH₂Si(CH₃)₂OCH₃, C₆F₁₃CH₂CH₂Si(CH₃)₂OCH₃, C₇F₁₅CH₂CH₂Si(CH₃)₂OCH₃, C₈F₁₇CH₂CH₂Si(CH₃)₂OCH₃, CF₃CH₂CH₂Si(CH₃)(H)OCH₃ and the like; alkoxysilane compounds obtained by substituting a methyl group moiety of methoxy group of the above-mentioned alkylmethoxysilanes or fluoroalkylmethoxysilanes with a C₂-C₁₈ monovalent hydrocarbon group; a compound obtained by substituting the methoxy group with —OC(CH₃)═CHCOCH₃, —OC(CH₃)═N—Si(CH₃)₃, —OC(CF₃)═N—Si(CH₃)₃, —O—CO—R¹⁰ (where R¹⁰ is a C₁-C₁₈ monovalent hydrocarbon group the hydrogen elements of which may partially or entirely be replaced with a fluorine element(s)), an alkyl sulfonate group the hydrogen elements of which may partially or entirely be replaced with a fluorine element(s), isocyanate group, amino group, dialkylamino group, isothiocyanate group, azide group, acetamide group, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring, oxazolidinone ring, morpholine ring, —NH—C(O)—Si(CH₃)₃, —N(H)₂₋ₕ(Si(H)ᵢR⁹₃₋ᵢ)ₕ (where R⁹ is a C₁-C₁₈ monovalent hydrocarbon group the hydrogen elements of which may partially or entirely be replaced with a fluorine element(s), h is an integer of 1 or 2, and i is an integer of from 0 to 2), chloro group, bromo group, iodo group, nitrile group or —CO—NH—Si(CH₃)₃; and the like.

The number of X¹ of the silylation agent, which is represented by 4-a-b in the general formula [1], is preferably 1 because the protective film is uniformly formed thereby.

It is preferable that R¹ of the general formula [1] mutually independently represents at least one group selected from C₁-C₁₈ monovalent hydrocarbon groups the hydrogen elements of which may partially or entirely be replaced with a fluorine element(s) and more preferably at least one group selected from CₘH₂ₘ₊₁ (m=1 to 18) and CₙF₂ₙ+1CH₂CH₂ (n=1 to 8) because the wettability of the unevenly patterned surface can be more reduced when the protective film is formed thereon, i.e., because a more excellent water repellency can be imparted to the surface. Additionally, it is preferable that m is 1 to 12 and n is 1 to 8 because the protective film can be formed on the unevenly patterned surface in a short time.

Moreover, the acid is preferably at least one selected from the group consisting of hydrogen chloride, sulfuric acid, perchloric acid, sulfonic acid represented by the following general formula [2] and its anhydride, carboxylic acid represented by the following general formula [3] and its anhydride, alkyl borate ester, aryl borate ester, boron tris(trifluoroacetate), trialkoxyboroxin, boron trifluoride and a silane compound represented by the following general formula [4].

R²S(O)₂OH [2]

[In the formula [2], R² represents a C₁-C₁₈ monovalent hydrocarbon group the hydrogen elements of which may partially or entirely be replaced with a fluorine element(s).]

R³COOH [3]

[In the formula [3], R³ represents a C₁-C₁₈ monovalent hydrocarbon group the hydrogen elements of which may partially or entirely be replaced with a fluorine element(s).]

(R⁴)_{c}Si(H)_{d}X²_{4-c-d} [4]

[In the formula [4], R⁴ mutually independently represents a C₁-C₁₈ monovalent hydrocarbon group the hydrogen elements of which may partially or entirely be replaced with a fluorine element(s). Additionally, X² mutually independently represents at least one group selected from the group consisting of chloro group, —OCO—R⁵ (R⁵ is a C₁-C₁₈ monovalent hydrocarbon group the hydrogen elements of which may partially or entirely be replaced with a fluorine element(s).) and —OS(O)₂—R⁶ (R⁶ is a C₁-C₁₈ monovalent hydrocarbon group the hydrogen elements of which may partially or entirely be replaced with a fluorine element(s).). c is an integer of from 1 to 3. d is an integer of from 0 to 2. The total of c and d is 1 to 3.]

Sulfonic acid represented by the general formula [2] and its anhydride are exemplified by methansulfonic acid, benzenesulfonic acid, p-toluenesulfonic acid, trifluoromethanesulfonic acid, trifluoromethanesulfonic anhydride and the like. Carboxylic acid represented by the general formula [3] and its anhydride are exemplified by acetic acid, trifluoroacetic acid, pentafluoropropionic acid, acetic anhydride, trifluoroacetic anhydride, pentafluoropropionic anhydride and the like. The silane compound represented by the general formula [4] is preferably a chlorosilane, alkyl silyl alkyl sulfonate or alkyl silyl ester, and exemplified by trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl trifluoroacetate, decyldimethylsilyl trifluoromethanesulfonate and the like.

Furthermore, the base is preferably at least one selected from the group consisting of ammonia, N,N,N′,N′-tetramethylethylenediamine, triethylenediamine, dimethylaniline, alkylamine, dialkylamine, trialkylamine, pyridine, piperazine, N-alkylmorpholine and a silane compound represented by the following general formula [5].

(R⁷)ₑSi(H)_{f}X³_{4-e-f} [5]

[In the formula [5], R⁷ mutually independently represents a C₁-C₁₈ monovalent hydrocarbon group the hydrogen elements of which may partially or entirely be replaced with a fluorine element(s). Additionally, X³ mutually independently represents a monovalent functional group of which element to be bonded to a silicon element is nitrogen, the monovalent functional group possibly containing a fluorine element or a silicon element. e is an integer of from 1 to 3. f is an integer of from 0 to 2. The total of e and f is 1 to 3.]

By virtue of the acid or base contained in the liquid chemical, the reaction between the silylation agent and a silanol group serving as a reaction site of the unevenly patterned surface of the silicon wafer is accelerated, so that it is possible to impart an excellent water repellency to the surface of the wafer by conducting a surface treatment with the use of the liquid chemical. Incidentally, the acid or base may constitute a part of the protective film.

With consideration given to a reaction-accelerating effect, it is preferable that the liquid chemical contains acid. Particularly, it is preferable that the acid is: a strong acid (Brönsted acid) such as hydrogen chloride, perchloric acid and the like; an alkane sulfonic acid the hydrogen elements of which are partially or entirely replaced with a fluorine element(s) or its anhydride, such as trifluoromethanesulfonic acid, trifluoromethanesulfonic anhydride and the like; carboxylic acid the hydrogen elements of which are partially or entirely replaced with a fluorine element(s) or its acid anhydride, such as trifluoroacetic acid, trifluoroacetic anhydride, pentafluoropropionic acid and the like; chlorosilane; alkyl silyl alkyl sulfonate the hydrogen elements of which are partially or entirely replaced with a fluorine element(s); or alkyl silyl ester the hydrogen elements of which are partially or entirely replaced with a fluorine element(s). Incidentally, alkyl silyl ester is formed such that an alkyl group and —O—CO—R′ group (where R′ is an alkyl group) are bonded to a silicon element. Moreover, the acid contained in the liquid chemical may be formed by a reaction. For example, upon causing a reaction between alkylchlorosilane and alcohol, alkylalkoxysilane produced thereby may be used as a silylation agent, hydrochloric acid produced thereby may be used as the acid, alcohol not consumed by the reaction may be used as the nonaqueous organic solvent, and the protective film-forming liquid chemical may be thus obtained. In this case, a step that ranges from mixing of alkylchlorosilane and alcohol to the acquirement of the liquid chemical is regarded as “a mixing step”.

In addition, the present invention is a liquid chemical for forming a water-repellent protective film, prepared by any of the above-mentioned methods for preparing a liquid chemical forming a water-repellent protective film. As the liquid chemical, it is preferable to use: one containing a mixture of 76 to 99.8999 mass % of at least one kind of nonaqueous organic solvent selected from the group consisting of hydrofluoroethers, hydrochlorofluorocarbons, polyalcohol derivatives having no OH group and lactone-based solvents, 0.1 to 20 mass % of at least one kind of silylation agent selected from the group consisting of alkoxyl silanes having CₓH₂ₓ₊₁ group (x=1 to 12) or C_{y}F_{2y+1}CH₂CH₂ group (y=1 to 8), trimethyldimethylaminosilane, trimethyldiethylaminosilane, butyldimethyl(dimethylamino)silane, butyldimethyl(diethylamino)silane, hexyldimethyl(dimethylamino)silane, hexyldimethyl(diethylamino)silane, octyldimethyl(dimethylamino)silane, octyldimethyl(diethylamino)silane, decyldimethyl(dimethylamino)silane, decyldimethyl(diethylamino)silane, dodecyldimethyl(dimethylamino)silane and dodecyldimethyl(diethylamino)silane and 0.0001 to 4 mass % of at least one kind of acid selected from the group consisting of trifluoroacetic acid, trifluoroacetic anhydride, trifluoromethanesulfonic acid, trifluoromethanesulfonic anhydride, trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl trifluoroacetate and decyldimethylsilyl trifluoromethanesulfonate; or one consisting only of the mixture.

As the liquid chemical, it is also preferable to use: one containing a mixture of 76 to 99.8999 mass % of at least one kind of nonaqueous organic solvent selected from the group consisting of hydrofluoroethers, hydrochlorofluorocarbons and polyalcohol derivatives having no OH group, 0.1 to 20 mass % of at least one kind of silylation agent selected from the group consisting of hexamethyldisilazane, tetramethyldisilazane, 1,3-dibutyltetramethyldisilazane, 1,3-dihexyltetramethyldisilazane, 1,3-dioctyltetramethyldisilazane, 1,3-didecyltetramethyldisilazane and 1,3-didodecyltetramethyldisilazane, and 0.0001 to 4 mass % of at least one kind of acid selected from the group consisting of trifluoroacetic acid, trifluoroacetic anhydride, trifluoromethanesulfonic acid, trifluoromethanesulfonic anhydride, trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl trifluoroacetate and decyldimethylsilyl trifluoromethanesulfonate; or one consisting only of the mixture.

A second embodiment of the present invention (the embodiment may hereinafter be referred to as “a second method”) is a method for preparing a liquid chemical kit for forming a water-repellent protective film (the liquid chemical kit may hereinafter be referred to merely as “a liquid chemical kit”), the liquid chemical kit being for forming a water-repellent protective film at the time of cleaning a wafer having at its surface an uneven pattern and containing silicon element at least at a part of the uneven pattern at least on surfaces of recessed portions of the uneven pattern, the liquid chemical kit comprising a treatment liquid (A) that contains a nonaqueous organic solvent and a silylation agent and a treatment liquid (B) that contains a nonaqueous organic solvent, and an acid or base. The method is characterized by comprising:

a dehydrating step for adjusting a water content of the nonaqueous organic solvent to 200 mass ppm or less;
a step of producing the treatment liquid (A), wherein the nonaqueous organic solvent and the silylation agent are mixed after the dehydrating step; and
a step of producing the treatment liquid (B), wherein the nonaqueous organic solvent and the acid or base are mixed after the dehydrating step.

In the dehydrating step, the water content of the nonaqueous organic solvent is adjusted to 200 mass ppm or less. With this, a reduction of the activity of the liquid chemical becomes difficult to occur while mixing the treatment liquids (A) and (B) (obtained by the subsequent steps of producing the treatment liquids (A) and (B), respectively) and using an obtained liquid chemical kit; therefore, it is possible to impart an excellent pot life to the liquid chemical obtained from the liquid chemical kit. A nonaqueous organic solvent having a water content of 100 mass ppm or less, preferably 50 mass ppm or less is more preferable because the liquid chemical for forming a water-repellent protective film, produced by mixing the liquid chemical kit gains the water-repellency-imparting effect and the pot life more excellently. Incidentally, the water content of the nonaqueous organic solvent after the dehydrating step is required only to be within the above-mentioned range and therefore it may be not lower than 0.1 mass ppm.

The dehydrating step is preferably at least one selected from the group consisting of a step of purifying the nonaqueous organic solvent by distillation, a step of removing water from the solvent by adding an insoluble water-absorbing agent to the nonaqueous organic solvent, a step of performing a substitution by a dried inert gas under exposure to air, and a step of heating or vacuum heating.

Additionally, the insoluble water-absorbing agent added to the nonaqueous organic solvent is preferably at least one selected from the group consisting of zeolite, phosphorus pentoxide, silica gel, calcium chloride, sodium sulfate, magnesium sulfate, anhydrous zinc chloride, fuming sulfuric acid and soda lime.

The nonaqueous organic solvent used in the second method of the present invention is exemplified by the same nonaqueous organic solvents as those usable in the first method.

The silylation agent used in the second method of the present invention is preferably at least one selected from the group consisting of silicon compounds represented by the general formula [1].

Further, the silylation agent is preferably a silicon compound represented by the following general formula [6].

R-SiX⁴_{4-g} [6]

[In the formula [6], R⁸ mutually independently represents at least one group selected from a hydrogen group and a C₁-C₁₈ monovalent hydrocarbon group the hydrogen elements of which may partially or entirely be replaced with a fluorine element(s), in which the total number of carbons contained in all of the hydrocarbon group(s) bonded to silicon element is not smaller than 6. Additionally, X⁴ mutually independently represents at least one group selected from a monovalent functional group of which element to be bonded to a silicon element is nitrogen, a monovalent functional group of which element to be bonded to a silicon element is oxygen, a halogen group, a nitrile group and —CO—NH—Si(CH₃)₃ group. g is an integer of from 1 to 3.]

R⁸ of the general formula [6] decreases a surface energy of an article thereby reducing the interaction between water or another liquid and the surface of the article (i.e., at the interface) such as a hydrogen bond, intermolecular forces and the like. The effect of reducing the interaction is particularly exhibited against water, but it is also exhibited against a mixture liquid of water and a liquid other than water or against a liquid other than water. With this, the contact angle of the liquid to the article surface can be increased. R⁸ behaves as a hydrophobic group, so that if the protective film is formed by using a bulky hydrophobic group the surface of the wafer exhibits a good water repellency after being subjected to a treatment. When the total number of carbons contained in all of the hydrocarbon group(s) that serves as R⁸ and bonded to silicon element is not smaller than 6, it is possible to produce a water repellent film exhibiting a sufficient water repellent performance even if the number of hydroxyl groups per unit area of the uneven pattern containing silicon element is low.

X⁴ of the general formula [6] is a reactive moiety having reactivity against silanol group that serves as a reaction site of a silicon wafer. The reactive moiety and silanol group of a wafer cause reaction, i.e., the silylation agent is chemically bonded to silicon element of the silicon wafer through a siloxane bond, thereby forming the protective film. In cleaning of a silicon wafer using a cleaning liquid, if the protective film has been formed on the surfaces of the recessed portions of the wafer at the time of removing or drying the cleaning liquid out of the recessed portions of the wafer, the capillary force of the surfaces of the recessed portions is so lowered as to make a pattern collapse difficult to occur.

Examples of the silicon compound represented by the general formula [6] are: chlorosilane-based compounds such as C₄H₉(CH₃)₂SiCl, C₅H₁₁(CH₃)₂SiCl, C₆H₁₃(CH₃)₂SiCl, C₇H₁₅(CH₃)₂SiCl, C₈H₁₇(CH₃)₂SiCl, C₉H₁₉(CH₃)₂SiCl, C₁₀H₂₁(CH₃)₂SiCl, C₁₁H₂₃(CH₃)₂SiCl, C₁₂H₂₅(CH₃)₂SiCl, C₁₃H₂₇(CH₃)₂SiCl, C₁₄H₂₉(CH₃)₂SiCl, C₁₅H₃₁(CH₃)₂SiCl, C₁₆H₃₃(CH₃)₂SiCl, C₁₇H₃₅(CH₃)₂SiCl, C₁₈H₃₇(CH₃)₂SiCl, C₅H₁₁(CH₃)HSiCl, C₆H₁₃(CH₃)HSiCl, C₇H₁₅(CH₃)HSiCl, C₈H₁₇(CH₃)HSiCl, C₉H₁₉(CH₃)HSiCl, C₁₀H₂₁(CH₃)HSiCl, C₁₁H₂₃(CH₃)HSiCl, C₁₂H₂₅(CH₃)HSiCl, C₁₃H₂₇(CH₃)HSiCl, C₁₄H₂₉(CH₃)HSiCl, C₁₅H₃₁(CH₃)HSiCl, C₁₆H₃₃(CH₃)HSiCl, C₁₇H₃₅(CH₃)HSiCl, C₁₈H₃₇(CH₃)HSiCl, C₂F₅C₂H₄(CH₃)₂SiCl, C₃F₇C₂H₄(CH₃)₂SiCl, C₄F₉C₂H₄(CH₃)₂SiCl, C₅F₁₁C₂H₄(CH₃)₂SiCl, C₆F₁₃C₂H₄(CH₃)₂SiCl, C₇F₁₅C₂H₄(CH₃)₂SiCl, C₈F₁₇C₂H₄(CH₃)₂SiCl, (C₂H₅)₃SiCl, C₃H₇(C₂H₅)₂SiCl, C₄H₉(C₂H₅)₂SiCl, C₅H₁₁(C₂H₅)₂SiCl, C₆H₁₃(C₂H₅)₂SiCl, C₇H₁₅(C₂H₅)₂SiCl, C₈H₁₇(C₂H₅)₂SiCl, C₉H₁₉(C₂H₅)₂SiCl, C₁₀H₂₁(C₂H₅)₂SiCl, C₁₁H₂₃(C₂H₅)₂SiCl, C₁₂H₂₅(C₂H₅)₂SiCl, C₁₃H₂₇(C₂H₅)₂SiCl, C₁₄H₂₉(C₂H₅)₂SiCl, C₁₅H₃₁(C₂H₅)₂SiCl, C₁₆H₃₃(C₂H₅)₂SiCl, C₁₇H₃₅(C₂H₅)₂SiCl, C₁₈H₃₇(C₂H₅)₂SiCl, (C₄H₉)₃SiCl, C₅H₁₁(C₄H₉)₂SiCl, C₆H₁₃(C₄H₉)₂SiCl, C₇H₁₅(C₄H₉)₂SiCl, C₈H₁₇(C₄H₉)₂SiCl, C₉H₁₉(C₄H₉)₂SiCl, C₁₀H₂₁(C₄H₉)₂SiCl, C₁₁H₂₃(C₄H₉)₂SiCl, C₁₂H₂₅(C₄H₉)₂SiCl, C₁₃H₂₇(C₄H₉)₂SiCl, C₁₄H₂₉(C₄H₉)₂SiCl, C₁₅H₃₁(C₄H₉)₂SiCl, C₁₆H₃₃(C₄H₉)₂SiCl, C₁₇H₃₅(C₄H₉)₂SiCl, C₁₈H₃₇(C₄H₉)₂SiCl, CF₃C₂H₄(C₄H₉)₂SiCl, C₂F₅C₂H₄(C₄H₉)₂SiCl, C₃F₇C₂H₄(C₄H₉)₂SiCl, C₄F₉C₂H₄(C₄H₉)₂SiCl, C₅F₁₁C₂H₄(C₄H₉)₂SiCl, C₆F₁₃C₂H₄(C₄H₉)₂SiCl, C₇F₁₅C₂H₄(C₄H₉)₂SiCl, C₈F₁₇C₂H₄(C₄H₉)₂SiCl, C₅H₁₁(CH₃)SiCl₂, C₆H₁₃(CH₃)SiCl₂, C₇H₁₅(CH₃)SiCl₂, C₈H₁₇(CH₃)SiCl₂, C₉H₁₉(CH₃)SiCl₂, C₁₀H₂₁(CH₃)SiCl₂, C₁₁H₂₃(CH₃)SiCl₂, C₁₂H₂₅(CH₃)SiCl₂, C₁₃H₂₇(CH₃)SiCl₂, C₁₄H₂₉(CH₃)SiCl₂, C₁₅H₃₁(CH₃)SiCl₂, C₁₆H₃₃(CH₃)SiCl₂, C₁₇H₃₅(CH₃)SiCl₂, C₁₈H₃₇(CH₃)SiCl₂, C₃F₇C₂H₄(CH₃)SiCl₂, C₄F₉C₂H₄(CH₃)SiCl₂, C₅F₁₁C₂H₄(CH₃)SiCl₂, C₆F₁₃C₂H₄(CH₃)SiCl₂, C₇F₁₅C₂H₄(CH₃)SiCl₂, C₈F₁₇C₂H₄(CH₃)SiCl₂, C₆H₁₃SiCl₃, C₇H₁₅SiCl₃, C₈H₁₇SiCl₃, C₉H₁₉SiCl₃, C₁₀H₂₁SiCl₃, C₁₁H₂₃SiCl₃, C₁₂H₂₅SiCl₃, C₁₃H₂₇SiCl₃, C₁₄H₂₉SiCl₃, C₁₅H₃₁SiCl₃, C₁₆H₃₃SiCl₃, C₁₇H₃₅SiCl₃, C₁₈H₃₇SiCl₃, C₄F₉C₂H₄SiCl₃, C₅F₁₁C₂H₄SiCl₃, C₆F₁₃C₂H₄SiCl₃, C₁₇F₁₅C₂H₄SiCl₃, C₈F₁₇C₂H₄SiCl₃ and the like; a compound obtained by substituting the chloro (Cl) group of the above-mentioned chlorosilanes with alkoxy group, —OC(CH₃)═CHCOCH₃, —OC(CH₃)═N—Si(CH₃)₃, —OC(CF₃)═N—Si(CH₃)₃, —O—CO—R¹⁰ (where R¹⁰ is a C₁-C₁₈ monovalent hydrocarbon group the hydrogen elements of which may partially or entirely be replaced with a fluorine element(s)), an alkyl sulfonate group the hydrogen elements of which may partially or entirely be replaced with a fluorine element(s), isocyanate group, amino group, dialkylamino group, isothiocyanate group, azide group, acetamide group, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring, oxazolidinone ring, morpholine ring, —NH—C(O)—Si(CH₃)₃, —N(H)₂₋ₕ(Si(H)ᵢR⁹₃₋ᵢ)ₕ (where R⁹ is a C₁-C₁₈ monovalent hydrocarbon group the hydrogen elements of which may partially or entirely be replaced with a fluorine element(s), h is an integer of 1 or 2, and i is an integer of from 0 to 2), bromo group, iodo group, nitrile group or —CO—NH—Si(CH₃)₃; and the like.

Additionally, g in the general formula [6] is required only to be an integer of from 1 to 3; however, when g is 1 or 2 and when a liquid chemical obtained from the liquid chemical kit is preserved for a long period of time, there is a possibility of causing polymerization of silicon compound due to the contamination of water content and the like to shorten a possible preservation period. In view of this, it is preferable that g in the general formula [6] is 3.

Moreover, among silicon compounds represented by the general formula [6], those in which one R⁸ is a C₄-C₁₈ hydrocarbon group the hydrogen elements of which may partially or entirely be replaced with a fluorine element(s) and the other R⁸ consist of two methyl groups are preferable since the rate of reaction against hydroxyl groups resident on the unevenly patterned surface or on the wafer surface is accelerated thereby. This is because steric hindrance due to hydrophobic group has a great influence upon the reaction rate and because it is preferable that an alkyl chain to be bonded to silicon element has the longest chain and two other shorter chains, in a reaction between hydroxyl group resident on the unevenly patterned surface or on the wafer surface and the silicon compound.

Furthermore, acid used in the second method of the present invention is exemplified by the same acids as those usable in the first method.

Furthermore, base used in the second method of the present invention is exemplified by the same bases as those usable in the first method.

By virtue of the acid or base contained in the treatment liquid (B), the reaction between the silylation agent and a silanol group serving as a reaction site of the unevenly patterned surface of the silicon wafer is accelerated in the liquid chemical for forming a water-repellent protective film which liquid chemical is produced by mixing the liquid chemical kit. With this, it is possible to impart an excellent water repellency to the surface of the wafer by conducting a surface treatment with the use of the liquid chemical. Incidentally, the acid or base may constitute a part of the protective film.

With consideration given to a reaction-accelerating effect, it is preferable that the treatment liquid (B) contains acid. Particularly, it is preferable that the acid is: a strong acid (Brönsted acid) such as hydrogen chloride, perchloric acid and the like; an alkane sulfonic acid the hydrogen elements of which are partially or entirely replaced with a fluorine element(s) or its anhydride, such as trifluoromethanesulfonic acid, trifluoromethanesulfonic anhydride and the like; carboxylic acid the hydrogen elements of which are partially or entirely replaced with a fluorine element(s) or its acid anhydride, such as trifluoroacetic acid, trifluoroacetic anhydride, pentafluoropropionic acid and the like; chlorosilane; alkyl silyl alkyl sulfonate the hydrogen elements of which are partially or entirely replaced with a fluorine element(s); or alkyl silyl ester the hydrogen elements of which are partially or entirely replaced with a fluorine element(s).

In addition, the present invention is a liquid chemical kit for forming a water-repellent protective film, prepared by any of the above-mentioned methods for preparing a liquid chemical kit for forming a water-repellent protective film. As the treatment liquid (A) of the liquid chemical kit, it is preferable to use: one containing a mixture of 60 to 99.8 mass % of at least one kind of nonaqueous organic solvent selected from the group consisting of hydrofluoroethers, hydrochlorofluorocarbons, polyalcohol derivatives having no OH group and lactone-based solvents and 0.2 to 40 mass % of at least one kind of silylation agent selected from the group consisting of alkoxyl silanes having CₓH₂ₓ₊₁ group (x=1 to 10) or C_{y}F_{2y+1}CH₂CH₂ group (y=1 to 8), trimethyldimethylaminosilane, trimethyldiethylaminosilane, butyldimethyl(dimethylamino)silane, butyldimethyl(diethylamino)silane, hexyldimethyl(dimethylamino)silane, hexyldimethyl(diethylamino)silane, octyldimethyl(dimethylamino)silane, octyldimethyl(diethylamino)silane, decyldimethyl(dimethylamino)silane, decyldimethyl(diethylamino)silane, dodecyldimethyl(dimethylamino)silane and dodecyldimethyl(diethylamino)silane; or one consisting only of the mixture. Furthermore, as the treatment liquid (B) of the liquid chemical kit, it is preferable to use: one containing a mixture of 60 to 99.9998 mass % of at least one kind of nonaqueous organic solvent selected from the group consisting of hydrofluoroethers, hydrochlorofluorocarbons, polyalcohol derivatives having no OH group and lactone-based solvents and 0.0002 to 40 mass % of at least one kind of acid selected from the group consisting of trifluoroacetic acid, trifluoroacetic anhydride, trifluoromethanesulfonic acid, trifluoromethanesulfonic anhydride, trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl trifluoroacetate and decyldimethylsilyl trifluoromethanesulfonate; or one consisting only of the mixture. Incidentally, at the time of preparing the liquid chemical for forming a water-repellent protective film by mixing the treatment liquid (A) and the treatment liquid (B), it is preferable that the nonaqueous organic solvent, the silylation agent and the acid are mixed in an amount of 76 to 99.8999 mass %, 0.1 to 20 mass % and 0.0001 to 4 mass %, respectively, relative to the total amount of 100 mass % of the liquid chemical after preparation.

As the treatment liquid (A) of the liquid chemical kit, it is preferable to use: one containing a mixture of 60 to 99.8 mass % of at least one kind of nonaqueous organic solvent selected from the group consisting of hydrofluoroethers, hydrochlorofluorocarbons and polyalcohol derivatives having no OH group and 0.2 to 40 mass % of at least one kind of silylation agent selected from the group consisting of hexamethyldisilazane, tetramethyldisilazane, 1,3-dibutyltetramethyldisilazane, 1,3-dihexyltetramethyldisilazane, 1,3-dioctyltetramethyldisilazane, 1,3-didecyltetramethyldisilazane and 1,3-didodecyltetramethyldisilazane; or one consisting only of the mixture. Furthermore, as the treatment liquid (B) of the liquid chemical kit, it is preferable to use: one containing a mixture of 60 to 99.9998 mass % of at least one kind of nonaqueous organic solvent selected from the group consisting of hydrofluoroethers, hydrochlorofluorocarbons and polyalcohol derivatives having no OH group and 0.0002 to 40 mass % of at least one kind of acid selected from the group consisting of trifluoroacetic acid, trifluoroacetic anhydride, trifluoromethanesulfonic acid, trifluoromethanesulfonic anhydride, trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl trifluoroacetate and decyldimethylsilyl trifluoromethanesulfonate; or one consisting only of the mixture. Incidentally, at the time of preparing the liquid chemical for forming a water-repellent protective film by mixing the treatment liquid (A) and the treatment liquid (B), it is preferable that the nonaqueous organic solvent, the silylation agent and the acid are mixed in an amount of 76 to 99.8999 mass %, 0.1 to 20 mass % and 0.0001 to 4 mass %, respectively, relative to the total amount of 100 mass % of the liquid chemical after preparation.

### Effects of the Invention

According to the preparation method of the present invention, it is possible to obtain a protective film-forming liquid chemical which can impart an excellent water repellency to an unevenly patterned surface of a silicon wafer so as to reduce the capillary force of the unevenly patterned surface of the wafer thereby improving a cleaning step which tends to induce a pattern collapse. Furthermore, according to the preparation method of the present invention, it is possible to obtain a protective film-forming liquid chemical having a good persistence (pot life) of the improving effect in particular. Moreover, according to the preparation method of the present invention, it is possible to produce a liquid chemical kit for forming a water-repellent protective film, the kit allowing providing the liquid chemical when mixed.

### MODE(S) FOR CARRYING OUT THE INVENTION

In most cases, a wafer having an uneven pattern at its surface can be obtained by the following procedures. First of all, a resist is applied to a smooth wafer surface. Thereafter, the resist is exposed through a resist mask, followed by conducting an etching removal on the exposed resist or the unexposed resist, thereby producing a resist having a desired uneven pattern. Additionally, a resist having an uneven pattern can be obtained also by pushing a mold having a pattern onto a resist. Then, the wafer is subjected to etching. At this time, recessed portions of a resist pattern are etched selectively. Finally, the resist is stripped off thereby obtaining a wafer having an uneven pattern.

A wafer having an uneven pattern at its surface and containing silicon element at least at a part of the uneven pattern includes: those on which surface a silicon-containing film such as silicon, silicon oxide and silicon nitride is formed; and those containing silicon element such as silicon, silicon oxide and silicon nitride when formed with the uneven pattern at least at a part of the uneven patterned surface.

Additionally, also concerning a wafer consisting of two or more components containing at least one selected from silicon, silicon oxide and silicon nitride, it is also possible to form a protective film at least on one surface selected from silicon, silicon oxide and silicon nitride. The wafer consisting of two or more components includes those on which surface at least one of silicon, silicon oxide and silicon nitride is formed and those formed with an uneven pattern and at least a part of the uneven pattern is at least one selected from silicon, silicon oxide and silicon nitride. Incidentally, where a protective film can be formed with the liquid chemical of the present invention is an unevenly patterned surface that corresponds to a part containing silicon element.

Concerning a contact angle, on the assumption that when the protective film is formed with the protective film-forming liquid chemical at least on the surfaces of the recessed portions of the uneven pattern of the wafer water is retained on the surfaces, it is preferable that a contact angle θ₁ (a contact angle in the case of using a liquid chemical preserved for a certain period of time) is not reduced to 15° or more smaller than a contact angle θ₀ (a contact angle in the case of using a liquid chemical within 10 minutes after preparation) (in other words, it is preferable that an equation represented by “θ₀−θ₁<15°” is satisfied). If the reduction of the contact angle is 15° or more, the water repellent performance of the protective film is not stably exhibited so as to raise a fear that an effect of improving a cleaning step which tends to induce a pattern collapse cannot endure sufficiently (i.e., the pot life is not good) and therefore this is not preferable. It is further preferable that both the contact angle θ₁ and the contact angle θ₀ are 50 to 130° because the pattern collapse becomes difficult to occur. Additionally, the closer to 90° the contact angle is, the smaller the capillary force acting on the recessed portions becomes. With this, the pattern collapse is made further difficult to occur, so that it is particularly preferable that the contact angle is 60 to 120°, much more preferably 70 to 110°. Incidentally, the liquid chemical for forming a water-repellent protective film, containing a nonaqueous organic solvent, a silylation agent, and an acid or base is preserved in an as-is state throughout the period from preparation to use; therefore, if the dehydrating step as in the first method of the present invention is not performed, the liquid chemical is deactivated under the influence of water content during the preservation so that the reduction of the contact angle reaches 15° or more. Accordingly, the liquid chemical prepared by the first method of the present invention is preferably one in which the reduction of the contact angle does not reach 15° or more during the preservation or one in which the reduction of the contact angle does not reach 15° or more within 4 weeks after the preparation, and more preferably one in which the reduction of the contact angle does not reach 15° or more within 12 weeks after the preparation. As a matter of course, a smaller reduction of the contact angle is more preferable because the water repellent performance of the protective film becomes stable. More specifically, it is preferable that the reduction of the contact angle does not reach 10° or more within 4 weeks after the preparation, and it is further preferable that the reduction of the contact angle does not reach 10° or more within 12 weeks after the preparation. In addition, the liquid chemical kit prepared by the second method of the present invention is preserved in a state of a liquid chemical kit over the period from preparation to use (in other words, the treatment liquid (A) and the treatment liquid (B) are separately preserved) and therefore a possibility that the treatment liquid (A) and the treatment liquid (B) are deactivated during this period is not serious but, if the dehydrating step as in the second method of the present invention is not performed, the liquid chemical is deactivated under the influence of water content while mixing the treatment liquid (A) and the treatment liquid (B), and using the obtained liquid chemical, so that the reduction of the contact angle reaches 15° or more. Accordingly, the liquid chemical kit prepared by the second method of the present invention is preferably one in which the reduction of the contact angle does not reach 15° or more while mixing the treatment liquid (A) and the treatment liquid (B), and using the obtained liquid chemical. For example, on a surface having many silanol groups (that serve as a reaction site), such as a surface of silicon oxide, it is preferable that the reduction of the contact angle does not reach 15° or more after mixing the treatment liquid (A) and the treatment liquid (B), and preserving it for 4 weeks, and it is further preferable that the reduction of the contact angle does not reach 10° or more after mixing and 4 weeks of preservation. Additionally, on a surface having few silanol groups (that serve as a reaction site), such as a surface of silicon nitride, it is preferable that the reduction of the contact angle does not reach 15° or more after mixing the treatment liquid (A) and the treatment liquid (B), and preserving it for 24 hours, and it is further preferable that the reduction of the contact angle does not reach 10° or more after mixing and 24 hours of preservation.

Formation of the water repellent protective film on the surfaces of the recessed portions of the wafer is achieved in such a manner that a reactive moiety of a silylation agent contained in the liquid chemical prepared in the present invention or the liquid chemical obtained from the liquid chemical kit is reacted with silanol group serving as a reaction site of the wafer, i.e., in such a manner that the silylation agent is chemically bonded to silicon element of the silicon wafer through a siloxane bond. The reactive moiety may be decomposed or deteriorated by water thereby being sometimes reduced in reactivity, so it is necessary not to bring the silicon compound into contact with water.

When the liquid chemical or the liquid chemical formed by mixing the liquid chemical kit contains the silylation agent in an amount of 0.1 to 50 mass % relative to the total amount of 100 mass % of the liquid chemical, a sufficient water repellency is imparted to the surfaces of the recessed portions of the wafer. Though a sufficient water repellency can be imparted to the recessed portions of the wafer even if the concentration of the silylation agent exceeds 50 mass % as a matter of course, the concentration is preferably 0.1 to 50 mass % in view of cost. Hence, in order to ease the reduction of reactivity of the reactive moiety of the silicon compound, it is important to lower the water content of the nonaqueous organic solvent that behaves as a primary component except for the silicon compound.

In the preparation method of the present invention, a nonaqueous organic solvent prepared to have a water content of 200 mass ppm or less by the dehydrating step is used. Also concerning the silylation agent and the acid or base (which are mixed with the nonaqueous organic solvent in the subsequent step), those prepared to have a reduced water content by the same treatment as in the dehydration step are preferably used since the reactivity of the reactive moiety of the silylation agent in the liquid chemical or the liquid chemical obtained from the liquid chemical kit becomes more difficult to decrease.

The dehydrating step and the mixing step of the first method of the present invention; and the dehydrating step, the step of producing the treatment liquid (A) and the step of producing the treatment liquid (B) of the second method of the present invention are preferably conducted under a sealed condition and in an inert atmosphere having a low possibility for the entry of water content. The liquid chemical prepared by the first method of the present invention and the treatment liquids (A) and (B) prepared by the second method of the present invention are preferably kept sealed in an airtight container in order to prevent the entry of water content, and it is further preferable that the interior of the airtight container is in an inert atmosphere. The thus hermetically kept liquid chemical or the liquid chemical kit (the treatment liquids (A) and (B)) is preferably unsealed immediately before use. Mixing of the liquid chemical kit is preferably carried out in an inert atmosphere.

In order to prevent the entry of water content to a maximum, the dehydrating step and the mixing step of the first method of the present invention are preferably performed in an inert atmosphere having a dew point of not higher than −70° C. In an inert atmosphere having a dew point of not higher than −70° C., the water content in the gas phase is not higher than 2 mass ppm, with which the possibility of water content entering into the treatment liquid is reduced.

Likewise, the dehydrating step and the step of producing the treatment liquid (A) and the step of producing the treatment liquid (B) of the second method of the present invention are preferably performed in an inert atmosphere having a dew point of not higher than −70° C., in order to prevent the entry of water content to a maximum. In an inert atmosphere having a dew point of not higher than −70° C., the water content in the gas phase is not higher than 2 mass ppm, with which the possibility of water content entering into the treatment liquid is reduced.

Additionally, the protective film-forming liquid chemical and the protective film-forming liquid chemical kit of the present invention may contain another additive and the like within a range not affecting the scope of the present invention. As the additive, it is possible to cite oxidizing agents such as hydrogen peroxide, ozone and the like, surfactants and the like. If a part of the uneven pattern of the wafer is formed of a material on which the protective film cannot be formed by the silicon compound, it is possible to add something allowing the protective film to be formed on the material. Furthermore, it is also possible to add another acid or base for other than catalytic effect.

### EXAMPLES

As apparent from the equation discussed in “BACKGROUND OF THE INVENTION” section to be represented by:

P=2×γ×cos θ/S

(γ: Surface tension, θ: Contact angle, S: Pattern width (the widths of the recessed portions)), a pattern collapse greatly depends on the contact angle of a cleaning liquid to the wafer surface, i.e. the contact angle of a liquid drop and on the surface tension of the cleaning liquid. In a case of a cleaning liquid retained in recessed portions of an uneven pattern, the contact angle of a liquid drop and the capillary force acting on the surfaces of the recessed portions (which force is regarded as being equal to the pattern collapse) are in correlation with each other, so that the pattern collapse can be effectively prevented by forming a protective film on the surfaces of the recessed portions and bringing the contact angle of the liquid drop to the protective film closer to 90° to reduce the capillary force acting on the recessed portions. In Examples, water, which is representative of a water-based cleaning liquid, was used as the cleaning liquid.

However, in the case of a wafer having an unevenly patterned surface, the pattern is so fine that the contact angle of waterdrop to the protective film formed on the unevenly patterned surface cannot exactly be evaluated.

An evaluation of the contact angle of waterdrop is conducted by dropping several microliters of waterdrop on a surface of a sample (a substrate) and then measuring an angle formed between the waterdrop and the substrate surface, as discussed in JIS R 3257 (Testing method of wettability of glass substrate surface). However, in the case of a wafer having a pattern, the contact angle is enormously large. This is because Wenzel's effect or Cassie's effect is caused so that an apparent contact angle of the waterdrop is increased under the influence of a surface shape (roughness) of the substrate upon the contact angle.

In view of the above, various kinds of evaluations were carried out in such a manner as to supply a liquid chemical of the present invention onto a wafer having a smooth surface to form a protective film on the wafer surface and regard the protective film as a protective film formed on a surface of a wafer having an unevenly patterned surface. In the present invention, there were used “a silicon wafer having a SiO₂ film” obtained by forming a silicon oxide layer on a silicon wafer having a smooth surface (this wafer is indicated by “SiO₂” in Tables) and “a silicon wafer having a SiN film” obtained by forming a silicon nitride layer on a silicon wafer having a smooth surface (this wafer is indicated by “SiN” in Tables).

Details will be discussed below. Hereinafter, there will be discussed: a method for evaluating a wafer to which a protective film-forming liquid chemical is supplied; preparation of the protective film-forming liquid chemical; and results of evaluation made after providing the protective film-forming liquid chemical to the wafer.

[Method for evaluating wafer to which protective film-forming liquid chemical is provided]

As a method for evaluating a wafer to which a protective film-forming liquid chemical is provided, the following evaluations (1) and (2) were performed.

(1) Evaluation of contact angle of protective film formed on wafer surface About 2 μl of pure water was dropped on a surface of a wafer on which a protective film was formed by a surface treatment using a liquid chemical, followed by measuring an angle (contact angle) formed between the waterdrop and the wafer surface by using a contact angle meter (produced by Kyowa Interface Science Co., Ltd.: CA-X Model).

(2) Evaluation of pot life of liquid chemical (or liquid chemical obtained from liquid chemical kit) On samples produced by conducting a surface treatment on a surface of the silicon wafer having a SiO₂ film and a surface of the silicon wafer having a SiN film with the use of a liquid chemical that had been preserved under a sealed condition for 4 weeks and 12 weeks after preparation, contact angles were measured according to “(1) Evaluation of Contact Angle of Protective Film formed on Wafer Surface” section thereby evaluating the persistence (pot life) of the water repellency-imparting effect of the liquid chemical. Additionally, also on samples produced by conducting a surface treatment on a surface of the silicon wafer having a SiO₂ film with the use of a liquid chemical that had been obtained from a prepared liquid chemical kit and then preserved under a sealed condition for 1 week and 4 weeks, similar evaluations were made. Furthermore, also on samples produced by conducting a surface treatment on a surface of the silicon wafer having a SiN film with the use of a liquid chemical that had been obtained from a prepared liquid chemical kit and then preserved under a sealed condition for 5 hours and 24 hours, similar evaluations were made.

### Example 1-1

### (1) Preparation of Protective Film-Forming Liquid Chemical

In a dehydrating step, a hydrofluoroether (produced by 3M Limited under the trade name of HFE-7100), which is a flame-resistant nonaqueous organic solvent having no OH group, was subjected to a water content removal in use of a molecular sieve 3A (produced by UNION SHOWA K.K.). As a result of measuring the water content of HFE-7100 that had been subjected to the water content removal by using Karl Fischer's moisture meter (available from KYOTO ELECTRONICS MANUFACTURING CO., LTD. under the trade name of MKC-610-DT), it was 34 mass ppm. In a subsequent mixing step, 3 g of trimethylmethoxysilane [(CH₃)₃SiOCH₃] as a silylation agent, 1 g of trifluoromethanesulfonic acid [CF₃SO₃H] as an acid and 96 g of HFE-7100 as a nonaqueous organic solvent that had been subjected to the water content removal as discussed above were mixed thereby obtaining a protective film-forming liquid chemical. Incidentally, the dehydrating step and the mixing step were performed in an inert atmosphere having a dew point of not higher than −70° C. In addition, the thus obtained liquid chemical was sealed and stored in an airtight container under an inert condition where a dew point is not higher than −70° C. Additionally, also in Examples and Comparative Examples that follow the present example, preparation of a liquid chemical or a liquid chemical kit (treatment liquids (A) and (B)) was carried out in an inert atmosphere having a dew point of not higher than −70° C. and the obtained liquid chemical and liquid chemical kit (the treatment liquids (A) and (B)) were sealed and stored in an airtight container under an inert condition where a dew point is not higher than −70° C.

(2) Cleaning of wafer A silicon wafer having a SiO₂ film (a silicon wafer formed having a thermal oxide film layer of 1 μm thickness on its surface) was immersed in 1 mass % hydrogen fluoride aqueous solution at room temperature for 2 minutes. Thereafter, the wafer was immersed in pure water for 1 minute, and then immersed in 2-propanol (iPA) for 1 minute.

(3) Surface Treatment on Wafer Surface, Using Protective Film-Forming Liquid Chemical

After cleaning the silicon wafer having a SiO₂ film, the wafer was immersed in the protective film-forming liquid chemical at 20° C. for 1 minute, the liquid chemical having been prepared according to the “(1) Preparation of Protective Film-Forming Liquid Chemical” section and not exceeding 10 minutes after the preparation. The wafer thereafter immersed in iPA for 1 minute and then immersed in pure water as a water-based cleaning liquid for 1 minute. Finally, the wafer was taken out of the pure water, followed by blowing air to remove the pure water from the surface.

The thus obtained wafer was evaluated in a manner discussed in the “Method for evaluating wafer to which protective film-forming liquid chemical is provided” section. As a result, it was confirmed that a wafer having an initial contact angle of smaller than 10° before the surface treatment came to have a contact angle of 88° after the surface treatment and to exhibit an excellent water repellency-imparting effect. Furthermore, as a result of evaluating the pot life of the liquid chemical used in the present example, a contact angle obtained after a surface treatment using a liquid chemical stored at 25° C. for 4 weeks was 88° and a contact angle obtained after a surface treatment using a liquid chemical stored at 25° C. for 12 weeks was 88°. With this, it was confirmed that the excellent water repellency-imparting effect was stably maintained even after the 12 weeks of storage.

TABLE 1

| | | | Dehydrating Step | | | Contact Angle | | Pot Life of | |
|---|---|---|---|---|---|---|---|---|---|
| | | | | Water | | before and after | | Liquid Chemical | |
| | | | | Content of | | Surface Treatment | | (Contact Angle after | |
| | | Non- | | Nonaqueous | | Initial | Contact | Surface Treatment) | |
| | Prep- | aqueous | | Organic | | Contact | Angle after | 25° C., | 25° C., |
| | aration | Organic | Dehydrating | Solvent | | Angle | Treatment | 4 Weeks | 12 Weeks |
| | Method | Solvent | Method | (mass ppm) | Wafer | (° ) | (° ) | Later (° ) | Later (° ) |
| Example 1-1 | First | HFE-7100 | Dehydration by | 34 | SiO₂ | <10 | 88 | 88 | 88 |
| | Method | | Molecular Sieve 3A | | | | | | |
| Example 1-2 | First | PGMEA | Dehydration by | 36 | SiO₂ | <10 | 90 | 90 | 90 |
| | Method | | Zeolum 4A | | | | | | |
| Example 1-3 | First | PGMEA | Dehydration by | 78 | SiO₂ | <10 | 90 | 88 | 87 |
| | Method | | Silica Gel | | | | | | |
| Example 1-4 | First | PGMEA | Dehydration by | 130 | SiO₂ | <10 | 90 | 87 | 78 |
| | Method | | Soda Lime | | | | | | |
| Example 1-5 | First | iPA | Dehydration by | 32 | SiO₂ | <10 | 66 | 66 | 66 |
| | Method | | Molecular Sieve 3A | | | | | | |
| Comparative | First | PGMEA | — | 320 | SiO₂ | <10 | 90 | 68 | 58 |
| Example 1-1 | Method | | | | | | | | |

### Example 1-2

The procedure of Example 1-1 was repeated with the exception of the following: in the dehydrating step, propylene glycol monomethyl ether acetate (PGMEA), which is a nonaqueous organic solvent having no OH group, was subjected to a water content removal in use of Zeolum 4A (produced by TOSOH CORPORATION) to be prepared; the PGMEA that had been subjected to the water content removal had a water content of 36 mass ppm; and in the subsequent mixing step, 5 g of hexamethyldisilazane [(CH₃)₃Si—NH—Si(CH₃)₃] as a silylation agent, 0.1 g of trifluoroacetic anhydride [(CF₃CO)₂O] as an acid and 94.9 g of PGMEA as a nonaqueous organic solvent that had been subjected to the water content removal as discussed above were mixed thereby obtaining a protective film-forming liquid chemical. The result is as shown in Table 1, from which it can be confirmed that a water repellency-imparting effect was excellently exhibited and stably maintained even after the 12 weeks of storage.

### Example 1-3

In the dehydrating step, PGMEA, which is a nonaqueous organic solvent having no OH group, was subjected to a water content removal in use of silica gel (produced by KANTO CHEMICAL CO., INC.) (the water content obtained after the dehydrating step was 78 mass ppm). With the exception that the above-mentioned nonaqueous organic solvent was used, the procedure of Example 1-2 was repeated. The result is as shown in Table 1, from which it can be confirmed that a water repellency-imparting effect was excellently exhibited and stably maintained even after the 12 weeks of storage.

### Example 1-4

In the dehydrating step, PGMEA was subjected to a water content removal in use of soda lime (produced by Central Glass Co., Ltd.) (the water content obtained after the dehydrating step was 130 mass ppm). With the exception that the above-mentioned nonaqueous organic solvent was used, the procedure of Example 1-2 was repeated. The result is as shown in Table 1, from which it can be confirmed that a water repellency-imparting effect was excellently exhibited and stably maintained even after the 12 weeks of storage, though it slightly decreased.

### Example 1-5

The procedure of Example 1-1 was repeated with the exception of the following: in the dehydrating step, isopropyl alcohol (iPA), which is a nonaqueous organic solvent having OH group, was subjected to a water content removal in use of a molecular sieve 3A (produced by UNION SHOWA K.K.) to be prepared; the iPA that had been subjected to the water content removal had a water content of 32 mass ppm; and in the subsequent mixing step, 10 g of trimethylchlorosilane [(CH₃)₃SiC1] and 90 g of iPA as a nonaqueous organic solvent that had been subjected to the water content removal as discussed above were mixed thereby obtaining a protective film-forming liquid chemical. Incidentally, in the protective film-forming liquid chemical obtained by the present example, trimethylchlorosilane was reacted with iPA, so that trimethylisopropoxysilane as a silylation agent and hydrogen chloride as an acid were formed and existed. The result is as shown in Table 1, from which it can be confirmed that a water repellency-imparting effect was exhibited and stably maintained even after the 12 weeks of storage.

### Comparative Example 1-1

The mixing step of Example 2 was repeated by using PGMEA that had not been subjected to a water content removal as a nonaqueous organic solvent (the water content of the PGMEA was 320 mass ppm), thereby obtaining a protective film-forming liquid chemical. An obtained wafer was evaluated in a manner discussed in the “Method for evaluating wafer to which protective film-forming liquid chemical is provided” section. As a result, it was confirmed that a wafer having an initial contact angle of smaller than 100 before the surface treatment came to have a contact angle of 90° after the surface treatment and to exhibit an excellent water repellency-imparting effect. However, a contact angle obtained after a surface treatment using a liquid chemical stored at 25° C. for 4 weeks was 68° and a contact angle obtained after a surface treatment using a liquid chemical stored at 25° C. for 12 weeks was 58°. With this, it was confirmed that a water repellency-imparting effect was not stably maintained. The result is shown in Table 1.

### Example 2-1

The procedure of Example 1-1 was repeated with the exception of the following: in the dehydrating step, diethylene glycol monoethyl ether acetate (DGEEA), which is a nonaqueous organic solvent having no OH group, was subjected to a water content removal in use of a molecular sieve 3A (produced by UNION SHOWA K.K.) to be prepared; the water content of the DGEEA that had been subjected to the water content removal was measured by using Karl Fischer's moisture meter (available from KYOTO ELECTRONICS MANUFACTURING CO., LTD. under the trade name of MKC-610-DT) and confirmed to be 28 mass ppm; in a step of producing a treatment liquid (A), 5 g of butyldimethyl(dimethylamino)silane [C₄H₉Si(CH₃)₂—N(CH₃)₂] as a silylation agent and 45 g of DGEEA as a nonaqueous organic solvent that had been subjected to the water content removal as discussed above were mixed thereby preparing a treatment liquid (A); in a step of producing a treatment liquid (B), 0.2 g of trifluoroacetic anhydride [(CF₃CO)₂O] as an acid and 49.8 g of DGEEA as a nonaqueous organic solvent that had been subjected to the water content removal as discussed above were mixed thereby preparing a treatment liquid (B); and the treatment liquid (A) and the treatment liquid (B) were mixed and then an obtained protective film-forming liquid chemical was used within 10 minutes. The thus obtained wafer was evaluated in a manner discussed in the “Method for evaluating wafer to which protective film-forming liquid chemical is provided” section. As a result, it was confirmed that a wafer having an initial contact angle of smaller than 10° before the surface treatment came to have a contact angle of 94° after the surface treatment and to exhibit an excellent water repellency-imparting effect. Furthermore, as a result of evaluating the pot life of the liquid chemical used in the present example, a contact angle obtained after a surface treatment using a liquid chemical stored at 25° C. for 1 week was 92° and a contact angle obtained after a surface treatment using a liquid chemical stored at 25° C. for 4 weeks was 90°. With this, it was confirmed that the excellent water repellency-imparting effect was stably maintained even after the 4 weeks of storage. The result is shown in Table 2.

TABLE 2

| | | | | Dehydrating Step | | | Contact Angle | | Pot Life of | |
|---|---|---|---|---|---|---|---|---|---|---|
| | | | | | Water | | before and after | | Liquid Chemical | |
| | | Nonaqueous | | | Content of | | Surface Treatment | | (Contact Angle after | |
| | | Organic Solvent | | | Nonaqueous | | Initial | Contact | Surface Treatment) | |
| | Prep- | Treatment | Treatment | | Organic | | Contact | Angle after | 25° C., | 25° C., |
| | aration | Liquid | Liquid | Dehydrating | Solvent | | Angle | Treatment | 1 Week | 4 Weeks |
| | Method | (A) | (B) | Method | (mass ppm) | Wafer | (° ) | (° ) | Later (° ) | Later (° ) |
| Example 2-1 | Second | DGEEA | DGEEA | Dehydration by | 28 | SiO₂ | <10 | 94 | 92 | 90 |
| | Method | | | Molecular Sieve 3A | | | | | | |
| Example 2-2 | Second | DGEEA | DGEEA | Dehydration by | 28 | SiO₂ | <10 | 100 | 100 | 98 |
| | Method | | | Molecular Sieve 3A | | | | | | |
| Example 2-3 | Second | PGMEA | GBL | Dehydration by | Both were | SiO₂ | <10 | 108 | 106 | 102 |
| | Method | | | Molecular Sieve 3A | 42 | | | | | |
| Example 2-4 | Second | PGDA | PGDA | Dehydration by | 38 | SiO₂ | <10 | 102 | 100 | 98 |
| | Method | | | Molecular Sieve 3A | | | | | | |
| Example 2-5 | Second | TPGDME | TPGDME | Dehydration by | 38 | SiO₂ | <10 | 98 | 97 | 94 |
| | Method | | | Molecular Sieve 3A | | | | | | |
| Example 2-6 | Second | 13BGDA | 13BGDA | Dehydration by | 32 | SiO₂ | <10 | 104 | 103 | 100 |
| | Method | | | Molecular Sieve 3A | | | | | | |
| Example 2-7 | Second | 14BGDA | 14BGDA | Dehydration by | 34 | SiO₂ | <10 | 98 | 98 | 94 |
| | Method | | | Molecular Sieve 3A | | | | | | |
| Example 2-8 | Second | DPGMEA | DPGMEA | Dehydration by | 32 | SiO₂ | <10 | 102 | 100 | 98 |
| | Method | | | Molecular Sieve 3A | | | | | | |
| Example 2-9 | Second | TEGBME | TEGBME | Dehydration by | 38 | SiO₂ | <10 | 102 | 102 | 98 |
| | Method | | | Molecular Sieve 3A | | | | | | |
| Example 2-10 | Second | PGMEA | PGMEA | Dehydration by | 36 | SiO₂ | <10 | 102 | 102 | 97 |
| | Method | | | Zeolum 4A | | | | | | |
| Example 2-11 | Second | DGEEA | DGEEA | Dehydration by | 160 | SiO₂ | <10 | 100 | 96 | 88 |
| | Method | | | Soda Lime | | | | | | |
| Comparative | Second | DGEEA | DGEEA | — | 400 | SiO₂ | <10 | 100 | 90 | 82 |
| Example 2-1 | Method | | | | | | | | | |

The procedure of Example 2-1 was repeated with the exception that 5 g of octyldimethyl(dimethylamino)silane [C₈H₁₇Si(CH₃)₂—N(CH₃)₂] as a silylation agent was used. The result is as shown in Table 2, from which it can be confirmed that a liquid chemical obtained from the liquid chemical kit exhibited a water repellency-imparting effect excellently and that the water repellency-imparting effect was stably maintained even after the 4 weeks of storage.

### Examples 2-3 to 2-9

Evaluations were carried out upon modifying the nonaqueous organic solvent used in Example 2-2. The results are as shown in Table 2, from which it can be confirmed that liquid chemicals obtained from the liquid chemical kit exhibited a water repellency-imparting effect excellently and that the water repellency-imparting effect was stably maintained even after the 4 weeks of storage.

By the way, “GBL” means γ-butyrolactone, “PGDA” means propylene glycol diacetate, “TPGDME” means tripropylene glycol dimethyl ether, “13BGDA” means 1,3-butylene glycol diacetate, “14BGDA” means 1,4-butylene glycol diacetate, “DPGMEA” means dipropylene glycol monomethyl ether acetate, and “TEGBME” means triethylene glycol butyl methyl ether.

### Example 2-10

The procedure of Example 2-1 was repeated with the exception of the following: in the dehydrating step, PGMEA was subjected to a water content removal in use of Zeolum 4A (produced by TOSOH CORPORATION) (the water content obtained after the dehydrating step was 36 mass ppm); and in the step of producing the treatment liquid (A), 5 g of octyldimethyl(dimethylamino)silane [C₈H₁₇Si(CH₃)₂—N(CH₃)₂] as a silylation agent and 45 g of PGMEA as a nonaqueous organic solvent that had been subjected to the water content removal as discussed above were mixed thereby preparing the treatment liquid (A). The result is as shown in Table 2, from which it can be confirmed that a liquid chemical obtained from the liquid chemical kit exhibited a water repellency-imparting effect excellently and that the water repellency-imparting effect was stably maintained even after the 4 weeks of storage.

### Example 2-11

The procedure of Example 2-2 was repeated with the exception that DGEEA that had been subjected to a water content removal in use of soda lime (produced by Central Glass Co., Ltd.) was used as the nonaqueous organic solvent (the water content obtained after the dehydrating step was 160 mass ppm). The result is as shown in Table 2, from which it can be confirmed that a liquid chemical obtained from the liquid chemical kit exhibited a water repellency-imparting effect excellently and that the water repellency-imparting effect was stably maintained even after the 4 weeks of storage, though it slightly decreased.

### Comparative Example 2-1

The procedure of Example 2-2 was repeated with the exception that DGEEA that had not been subjected to a water content removal was used as the nonaqueous organic solvent (the water content was 400 mass ppm). As a result, it was confirmed that a wafer having an initial contact angle of smaller than 10° before the surface treatment came to have a contact angle of 100° after the surface treatment and that a liquid chemical obtained from the liquid chemical kit exhibited a water repellency-imparting effect excellently. However, as a result of evaluating the pot life of the liquid chemical used in the present comparative example, a contact angle obtained after a surface treatment using a liquid chemical stored at 25° C. for 1 week was 90° and a contact angle obtained after a surface treatment using a liquid chemical stored at 25° C. for 4 weeks was 82°. With this, it was confirmed that the water repellency-imparting effect was not stably maintained. The result is shown in Table 2.

### Example 3-1

The procedure of Example 1-2 was repeated with the exception that “a silicon wafer having a SiN film” obtained by forming a silicon nitride layer on a silicon wafer having a smooth surface (a silicon wafer formed having a silicon nitride layer of 50 nm thickness on its surface) was used. The thus obtained wafer was evaluated in a manner discussed in the “Method for evaluating wafer to which protective film-forming liquid chemical is provided” section. As a result, it was confirmed that a wafer having an initial contact angle of smaller than 10° before the surface treatment came to have a contact angle of 64° after the surface treatment and to exhibit a water repellency-imparting effect. Furthermore, as a result of evaluating the pot life of the liquid chemical used in the present example, a contact angle obtained after a surface treatment using a liquid chemical stored at 25° C. for 4 weeks was 64° and a contact angle obtained after a surface treatment using a liquid chemical stored at 25° C. for 12 weeks was 62°. With this, it was confirmed that the water repellency-imparting effect was stably maintained even after the 12 weeks of storage. The result is shown in Table 3.

TABLE 3

| | | | Dehydrating Step | | | Contact Angle | | Pot Life of | |
|---|---|---|---|---|---|---|---|---|---|
| | | | | Water | | before and after | | Liquid Chemical | |
| | | | | Content of | | Surface Treatment | | (Contact Angle after | |
| | | Non- | | Nonaqueous | | Initial | Contact | Surface Treatment) | |
| | Prep- | aqueous | | Organic | | Contact | Angle after | 25° C., | 25° C., |
| | aration | Organic | Dehydrating | Solvent | | Angle | Treatment | 4 Weeks | 12 Weeks |
| | Method | Solvent | Method | (mass ppm) | Wafer | (° ) | (° ) | Later (° ) | Later (° ) |
| Example 3-1 | First | PGMEA | Dehydration by | 36 | SiN | <10 | 64 | 64 | 62 |
| | Method | | Zeolum 4A | | | | | | |
| Comparative | First | PGMEA | — | 320 | SiN | <10 | 64 | 50 | 42 |
| Example 3-1 | Method | | | | | | | | |

### Comparative Example 3-1

The procedure of Comparative Example 1-1 was repeated with the exception that “a silicon wafer having a SiN film” obtained by forming a silicon nitride layer on a silicon wafer having a smooth surface (a silicon wafer formed having a silicon nitride layer of 50 nm thickness on its surface) was used. The thus obtained wafer was evaluated in a manner discussed in the “Method for evaluating wafer to which protective film-forming liquid chemical is provided” section. As a result, it was confirmed that a wafer having an initial contact angle of smaller than 10° before the surface treatment came to have a contact angle of 64° after the surface treatment and to exhibit a water repellency-imparting effect. However, as a result of evaluating the pot life of the liquid chemical used in the present comparative example, a contact angle obtained after a surface treatment using a liquid chemical stored at 25° C. for 4 weeks was 50° and a contact angle obtained after a surface treatment using a liquid chemical stored at 25° C. for 12 weeks was 42°. With this, it was confirmed that the water repellency-imparting effect was not stably maintained. The result is shown in Table 3.

### Example 4-1

The procedure of Example 2-2 was repeated with the exception that “a silicon wafer having a SiN film” obtained by forming a silicon nitride layer on a silicon wafer having a smooth surface (a silicon wafer formed having a silicon nitride layer of 50 nm thickness on its surface) was used. The thus obtained wafer was evaluated in a manner discussed in the “Method for evaluating wafer to which protective film-forming liquid chemical is provided” section. As a result, it was confirmed that a wafer having an initial contact angle of smaller than 10° before the surface treatment came to have a contact angle of 84° after the surface treatment and to exhibit an excellent water repellency-imparting effect. Furthermore, as a result of evaluating the pot life of the liquid chemical used in the present example, a contact angle obtained after a surface treatment using a liquid chemical stored at 25° C. for 5 hours was 83° and a contact angle obtained after a surface treatment using a liquid chemical stored at 25° C. for 24 hours was 82°. With this, it was confirmed that the excellent water repellency-imparting effect was stably maintained even after the 24 hours of storage. The result is shown in Table 4.

TABLE 4

| | | | | Dehydrating Step | | | Contact Angle | | Pot Life of | |
|---|---|---|---|---|---|---|---|---|---|---|
| | | | | | Water | | before and after | | Liquid Chemical | |
| | | Nonaqueous | | | Content of | | Surface Treatment | | (Contact Angle after | |
| | | Organic Solvent | | | Nonaqueous | | Initial | Contact | Surface Treatment) | |
| | Prep- | Treatment | Treatment | | Organic | | Contact | Angle after | 25° C., | 25° C., |
| | aration | Liquid | Liquid | Dehydrating | Solvent | | Angle | Treatment | 5 Hours | 24 Hours |
| | Method | (A) | (B) | Method | (mass ppm) | Wafer | (° ) | (° ) | Later (° ) | Later (° ) |
| Example 4-1 | Second | DGEEA | DGEEA | Dehydration by | 28 | SiN | <10 | 84 | 83 | 82 |
| | Method | | | Molecular Sieve 3A | | | | | | |
| Example 4-2 | Second | PGMEA | GBL | Dehydration by | Both were | SiN | <10 | 88 | 88 | 87 |
| | Method | | | Molecular Sieve 3A | 42 | | | | | |
| Example 4-3 | Second | PGDA | PGDA | Dehydration by | 38 | SiN | <10 | 86 | 86 | 85 |
| | Method | | | Molecular Sieve 3A | | | | | | |
| Example 4-4 | Second | TPGDME | TPGDME | Dehydration by | 38 | SiN | <10 | 82 | 82 | 82 |
| | Method | | | Molecular Sieve 3A | | | | | | |
| Example 4-5 | Second | 13BGDA | 13BGDA | Dehydration by | 32 | SiN | <10 | 88 | 86 | 84 |
| | Method | | | Molecular Sieve 3A | | | | | | |
| Example 4-6 | Second | 14BGDA | 14BGDA | Dehydration by | 34 | SiN | <10 | 82 | 80 | 80 |
| | Method | | | Molecular Sieve 3A | | | | | | |
| Example 4-7 | Second | DPGMEA | DPGMEA | Dehydration by | 32 | SiN | <10 | 86 | 84 | 84 |
| | Method | | | Molecular Sieve 3A | | | | | | |
| Example 4-8 | Second | TEGBME | TEGBME | Dehydration by | 38 | SiN | <10 | 84 | 80 | 78 |
| | Method | | | Molecular Sieve 3A | | | | | | |
| Comparative | Second | DGEEA | DGEEA | — | 400 | SiN | <10 | 82 | 70 | 60 |
| Example 4-1 | Method | | | | | | | | | |

Evaluations were carried out upon modifying the nonaqueous organic solvent used in Example 4-1. The results are as shown in Table 4, from which it can be confirmed that liquid chemicals obtained from the liquid chemical kit exhibited a water repellency-imparting effect excellently and that the water repellency-imparting effect was stably maintained even after the 24 hours of storage.

### Comparative Example 4-1

The procedure of Comparative Example 2-1 was repeated with the exception that “a silicon wafer having a SiN film” obtained by forming a silicon nitride layer on a silicon wafer having a smooth surface (a silicon wafer formed having a silicon nitride layer of 50 nm thickness on its surface) was used. As a result, it was confirmed that a wafer having an initial contact angle of smaller than 10° before the surface treatment came to have a contact angle of 82° after the surface treatment and that a liquid chemical obtained from the liquid chemical kit exhibited a water repellency-imparting effect. However, as a result of evaluating the pot life of the liquid chemical used in the present comparative example, a contact angle obtained after a surface treatment using a liquid chemical stored at 25° C. for 5 hours was 70° and a contact angle obtained after a surface treatment using a liquid chemical stored at 25° C. for 24 hours was 60°. With this, it was confirmed that the water repellency-imparting effect was not stably maintained. The result is shown in Table 4.

1.-8. (canceled)

9. A method for preparing a liquid chemical kit for forming a water-repellent protective film, the liquid chemical kit being for forming the water-repellent protective film at the time of cleaning a wafer having at its surface an uneven pattern and containing a silicon element at least at a part of the uneven pattern at least on surfaces of recessed portions of the uneven pattern, the liquid chemical kit comprising a treatment liquid (A) that contains a nonaqueous organic solvent and a silylation agent and a treatment liquid (B) that contains a nonaqueous organic solvent, and an acid or a base, the method comprising:
adjusting a water content of the nonaqueous organic solvent to 200 mass ppm or less by dehydration;
mixing the nonaqueous organic solvent and the silvlation agent producing the treatment liquid (A) after the adjusting step; and
mixing the nonaqueous organic solvent and the acid or the base producing the treatment liquid (B) after the adjusting step.

10. A method for preparing the liquid chemical kit for forming the water-repellent protective film, as claimed in claim 9, wherein the adjusting step is at least one selected from the group consisting of
purifying the nonaqueous organic solvent by distillation,
removing water from the nonaqueous organic solvent by adding an insoluble water-absorbing agent to the nonaqueous organic solvent,
performing a substitution of a dried inert gas for the water content of the nonaqueous organic solvent by exposing the nonaqueous organic solvent to the dried inert gas, and
heating or vacuum heating.

11. A method for preparing the liquid chemical kit for forming the water-repellent protective film, as claimed in claim 10, wherein the insoluble water-absorbing agent added to the nonaqueous organic solvent is at least one selected from the group consisting of zeolite, phosphorus pentoxide, silica gel, calcium chloride, sodium sulfate, magnesium sulfate, anhydrous zinc chloride, fuming sulfuric acid and soda lime.

12. A method for preparing the liquid chemical kit for forming the water-repellent protective film, as claimed in claim 9, wherein the nonaqueous organic solvent is at least one selected from the group consisting of hydrocarbons, esters, ethers, ketones, halogen-containing solvents, sulfoxide-based solvents, lactone-based solvents, carbonate-based solvents, polyalcohol derivatives having no OH group, and nitrogen element-containing solvents having no N—H group.

13. A method for preparing the liquid chemical kit for forming the water-repellent protective film, as claimed in claim 9, wherein the silylation agent is at least one selected from the group consisting of silicon compounds represented by the following general formula [1]
(R¹)ₐSi(H)b_{b}X¹_{4-a-b} [1]
wherein
R¹ mutually independently represents a monovalent organic group having a C₁-C₁₈ monovalent hydrocarbon group, wherein hydrogen may partially or entirely be replaced with fluorine;
X¹ mutually independently represents at least one group selected from the group consisting of a monovalent functional group wherein nitrogen is to be bonded to a silicon element, a monovalent functional group wherein oxygen is to be bonded to a silicon element, a halogen group, a nitrile group and a —CO—NH—Si(CH₃)₃ group;
a is an integer between 1 and 3;
b is an integer between 0 and 2, and
a+b is 1 to 3.

14. A method for preparing the liquid chemical kit for forming the water-repellent protective film, as claimed in claim 9, wherein the silylation agent is a silicon compound represented by the following general formula [6]
R⁸_{g}SiX⁴_{4-g} [6]
wherein
R⁸ mutually independently represents at least one group selected from a hydrogen group and a C₁-C₁₈ monovalent hydrocarbon group, wherein hydrogen may partially or entirely be replaced with fluorine and the total number of carbons contained in all of the hydrocarbon group(s) bonded to a silicon element is not smaller than 6;
X⁴ mutually independently represents at least one group selected from a monovalent functional group wherein nitrogen is to be bonded to a silicon element, a monovalent functional group wherein oxygen is to be bonded to a silicon element, a halogen group, a nitrile group and a —CO—NH—Si(CH₃)₃ group; and
g is an integer between 1 and 3.

15. A method for preparing the liquid chemical kit for forming the water-repellent protective film, as claimed in claim 9, wherein the acid is at least one selected from the group consisting of hydrogen chloride, sulfuric acid, perchloric acid, sulfonic acid represented by the following general formula [2] and its anhydride, carboxylic acid represented by the following general formula [3] and its anhydride, alkyl borate ester, aryl borate ester, boron tris(trifluoroacetate), trialkoxyboroxin, boron trifluoride and a silane compound represented by the following general formula [4]
R²S(O)₂OH [2]
wherein R² represents a C₁-C₁₈ monovalent hydrocarbon group wherein hydrogen may partially or entirely be replaced with fluorine
R³COOH [3]
wherein R³ represents a C₁-C₁₈ monovalent hydrocarbon group wherein hydrogen may partially or entirely be replaced with fluorine
(R⁴)_{c}Si(H)_{d}X²_{4-c-d} [4]
wherein
R⁴ mutually independently represents a C₁-C₁₈ monovalent hydrocarbon group wherein hydrogen may partially or entirely be replaced with fluorine;
X² mutually independently represents at least one group selected from the group consisting of a chloro group, —OCO—R⁵ wherein R⁵ is a C₁-C₁₈ monovalent hydrocarbon group wherein hydrogen may partially or entirely be replaced with fluorine, and —OS(O)₂—R⁶ wherein R⁶ is a C₁-C₁₈ monovalent hydrocarbon group wherein hydrogen may partially or entirely be replaced with fluorine;
c is an integer between 1 and 3;
d is an integer between 0 and 2; and
c+d is 1 to 3.

16. A method for preparing the liquid chemical kit for forming the water-repellent protective film, as claimed in claim 9, wherein the base is at least one selected from the group consisting of ammonia, N,N,N′,N′-tetramethylethylenediamine, triethylenediamine, dimethylaniline, alkylamine, dialkylamine, trialkylamine, pyridine, piperazine, N-alkylmorpholine and a silane compound represented by the following general formula [5]
(R⁷)ₑSi(H)_{f}X³_{4-e-f} [5]
wherein
R⁷ mutually independently represents a C₁-C₁₈ monovalent hydrocarbon group, wherein hydrogen may partially or entirely be replaced with fluorine;
X³ mutually independently represents a monovalent functional group, wherein nitrogen is to be bonded to a silicon element, the monovalent functional group optionally containing a fluorine element or a silicon element;
e is an integer between 1 and 3;
f is an integer between 0 and 2; and
e+f is 1 to 3.

17. (canceled)

18. A method for preparing a liquid chemical for forming a water-repellent protective film, comprising the steps of
mixing the treatment liquid (A) and the treatment liquid (B) of the liquid chemical kit prepared by the method as claimed in claim 9.

19. A method for cleaning a surface of a water having at its surface an uneven pattern and containing a silicon element at least at a part of the uneven pattern, comprising the steps of
preparing a liquid chemical for forming a water-repellent protective film, by mixing the treatment liquid (A) and the treatment liquid (B) of the liquid chemical kit prepared by the method as claimed in claim 9; and
using the liquid chemical.
